(19) United States
(12) Patent Application Publication
(10) Pub. No.: US 2001/0025607 A1
(43) Pub. Date: Oct. 4, 2001

(54) Microwave plasma reactor and method

(76) Inventors: Tony Lebar, Santa Clara, CA (US); Fan Cheung Sze, San Jose, CA (US); John T. Davies, El Sobrante, CA (US)

Correspondence Address: Edward S. Wright, FLEHR HOHBACH TEST, ALBRITTON & HERBERT LLP, Four Embarcadero Center, Suite 3400, San Francisco, CA, 94111-4187, US

(21) Appl. No.: 09/745,140

(22) Filed: Dec. 20, 2000

Related U.S. Application Data
(60) Provisional application No. 60/171,803, filed on Dec. 22, 1999.
(60) Provisional application No. 60/171,855, filed on Dec. 22, 1999.
(60) Provisional application No. 60/193,790, filed on Mar. 31, 2000.

(51) Int. Cl. C23C 16/00

(52) U.S. Cl. 118/723 MW; 427/575

(57) ABSTRACT

Plasma reactor having a generally cylindrical reaction chamber which is substantially greater in diameter than in height, a generally cylindrical waveguide which is aligned axially with the reaction chamber, and a window which separates the waveguide from the reaction chamber and permits microwave energy to pass from the waveguide to chamber to ionize gas and form a plasma in the chamber. In some embodiments, the microwave energy is applied initially in pulses and thereafter as a continuous wave in order to avoid the need for retuning upon ignition of the plasma, and in others the need for retuning is avoided by the use of fins which lock in a desired mode of operation.

This is based upon Provisional Application No. 60/171,803, filed Dec. 22, 1999, Provisional Application No. 60/171,855, filed Dec. 22, 1999, and Provisional Application No. 60/193,790, filed Mar. 31, 2000.

This invention pertains generally to the generation of ionized gas plasmas for use in the processing of semiconductor wafers and other workpieces and, more particularly, to a microwave plasma reactor and method.

In the past, microwave plasma reactors for use in the fabrication of semiconductor wafers have been relatively complex and costly to implement. They have employed techniques such as electron cyclotron resonance to ignite and maintain the plasma, increase the probability of sustaining removal rates, and direct the plasma to the workpiece. Such reactors are more efficient than inductively coupled and other radio frequency reactors, but they generally work well only at very low chamber pressures because of excessive collisions which tend to suppress the resonance at higher pressures.

In inductively coupled plasma sources, ion density and ion energy are separately controllable through the RF power applied to the inductive coil and RF bias applied to the wafer pedestal. However, these features lead to inefficient plasma uniformity in the chamber and the need for gas distribution plenums and baffles. They also contribute to power loss through the coil, which makes it difficult to maintain and repeat processes.

Another problem with microwave plasma generators is that microwave applicators using continuous wave microwave energies must generally be retuned after the plasma is started. Ignition of the plasma produces a sudden change in the load of the applicator, and retuning is necessary in order to maximize the coupling of energy tot he plasma. The retuning is typically done by means of tuning stubs or sliding shorts.

It is in general an object of the invention to provide a new and improved microwave plasma reactor and method.

Another object of the invention is to provide a microwave plasma reactor and method of the above character which overcome the limitations and disadvantages of plasma reactors heretofore provided.

These and other objects are achieved in accordance with the invention by providing a plasma reactor having a generally cylindrical reaction chamber which is substantially greater in diameter than in height, a generally cylindrical waveguide which is aligned axially with the reaction chamber, and a window which separates the waveguide from the reaction chamber and permits microwave energy to pass from the waveguide to chamber to ionize gas and form a plasma in the chamber. In some embodiments, the microwave energy is applied initially in pulses and thereafter as a continuous wave in order to avoid the need for retuning upon ignition of the plasma, and in others the need for retuning is avoided by the use of fins which lock in a desired mode of operation in the waveguide.

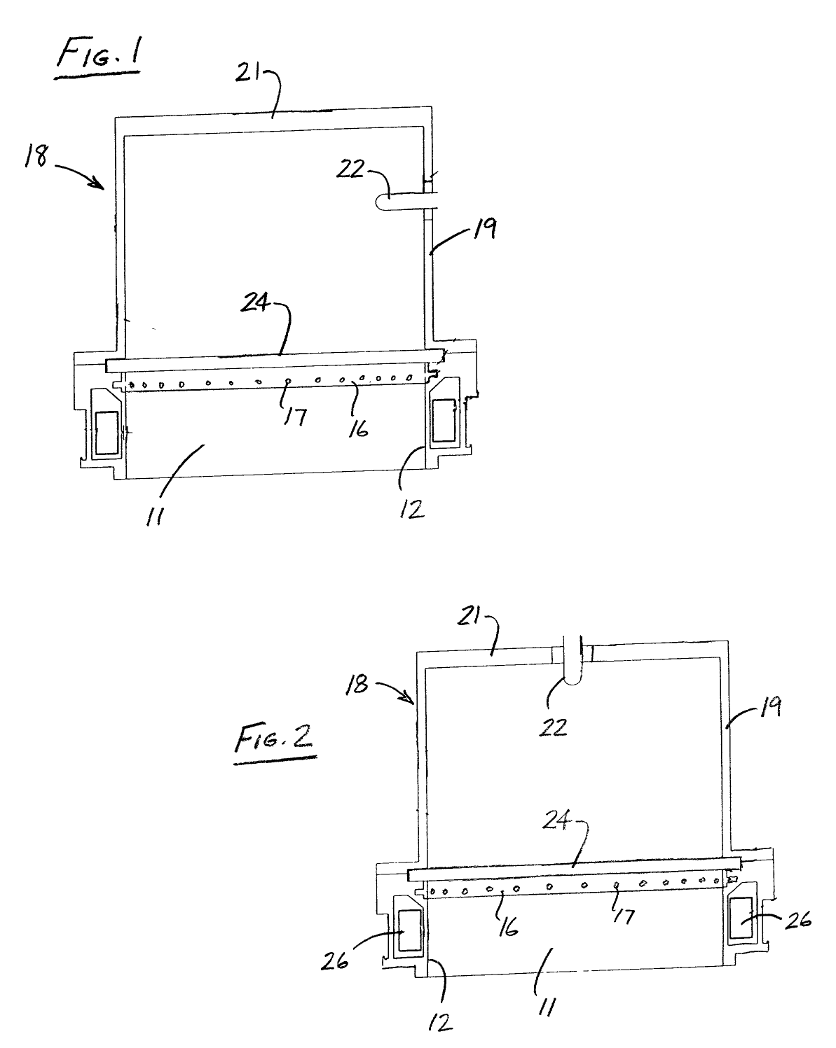

FIG. 1 is a vertical sectional view of one embodiment of a microwave plasma reactor incorporating the invention.

FIG. 2 is a vertical sectional view of another embodiment of a microwave plasma reactor incorporating the invention.

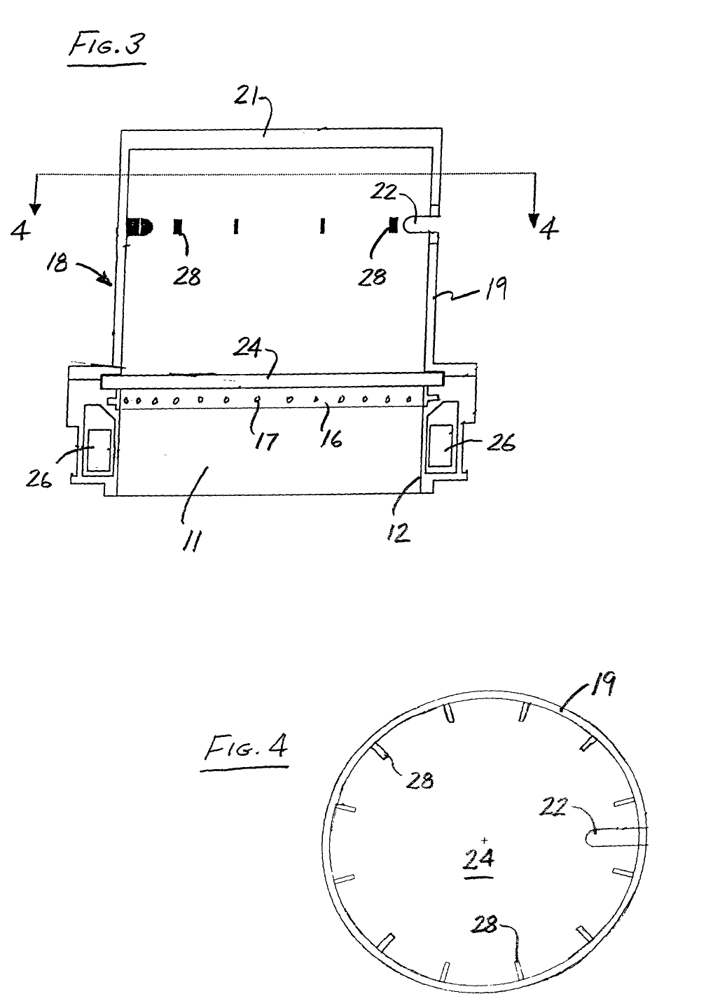

FIG. 3 is a vertical sectional view of another embodiment of a microwave plasma reactor incorporating the invention.

FIG. 4 is a cross-sectional view taken along line 4-4 in FIG. 3.

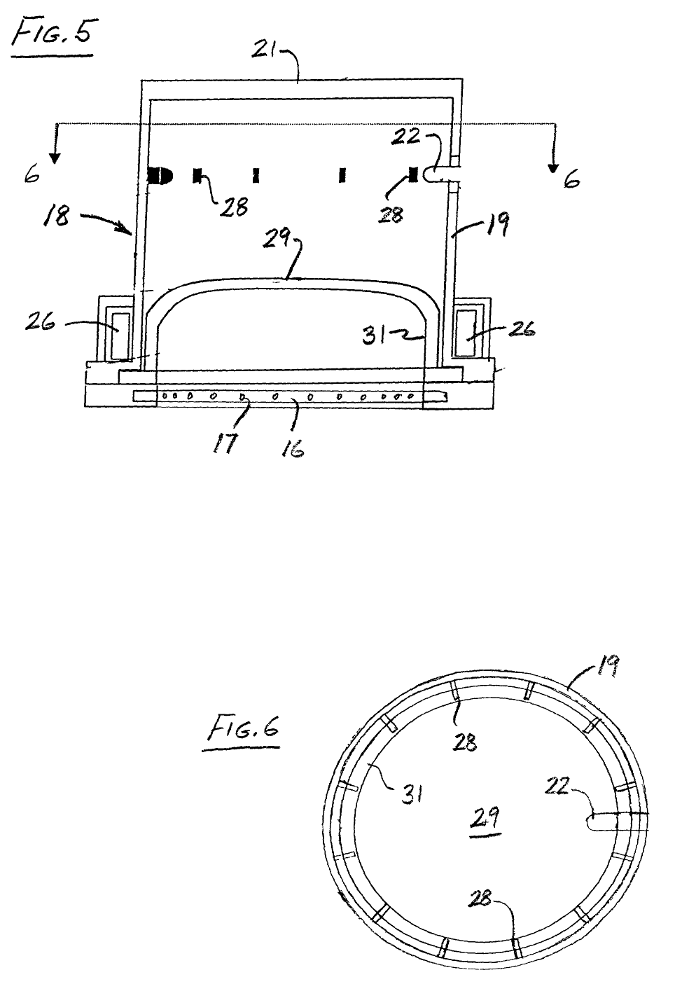

FIG. 5 is a vertical sectional view of another embodiment of a microwave plasma reactor incorporating the invention.

FIG. 6 is a cross-sectional view taken along line 6-6 in FIG. 5.

As illustrated in FIG. 1, the reactor includes a relatively flat, generally cylindrical reaction chamber 11 in which a semiconductor wafer or other workpiece (not shown) is processed. The chamber has a cylindrical side wall 12, with the diameter of the chamber being substantially greater than the height. In the embodiment illustrated the diameter of the chamber is approximately three times the height.

An annular manifold 16 surrounds the side wall of the chamber, with inwardly facing gas openings 17 spaced about the periphery of the chamber for distributing gas evenly within the chamber.

A microwave applicator 18 comprising a generally cylindrical waveguide 19 is positioned above the chamber for introducing microwave energy into the chamber to ionize the gas and form a gas plasma within the chamber. The waveguide has a diameter approximately equal to that of the chamber, and a length somewhat less than the diameter. The end of the waveguide opposite the chamber is closed by a flat plate 21. Both the side wall and the end plate are fabricated of a metal such as aluminum which, if desired, can be coated with a film of another metal such as gold, silver or tin. The end plate is attached to the side wall in a fixed position and does not need to be adjusted either during or after ignition of the plasma.

Microwave energy is supplied to the waveguide by an antenna 22 which is mounted in the side wall of the waveguide and connected to a microwave generator or magnetron (not shown). The source can operate at any desired microwave frequency ranging from a few hundred megahertz to a few gigahertz, typically 915 MHz or 2.45 GHz.

The reaction chamber is separated from the waveguide by dielectric window 24 in the form of a flat circular plate having a diameter at least as great as the reaction chamber. This window is fabricated of quartz, alumina or any other dielectric material, or combination of dielectric materials, which allows microwaves to pass freely.

Although the dielectric window is transparent to microwaves, it is not transparent to plasma, and it confines the plasma to the reaction chamber. It also serves as a vacuum window, with the pressure in the waveguide being at an atmospheric level and the pressure in the reaction chamber being on the order of a few millitorrs to several Torrs.

A plurality of permanent magnets 26 are spaced about the periphery of the reaction chamber outside side wall 12. These magnets improve the coupling between the microwaves and the gas, and they also reduce diffusion loss of the plasma to the chamber wall. The number of magnets required is dependent upon the diameter of the chamber and the size of the magnets. If desired, the magnets can be omitted.

The embodiment of FIG. 2 is similar to that of FIG. 1, and like reference numerals designate corresponding elements in the two embodiments. In the embodiment of FIG. 2, the microwave antenna 22 is mounted at the center of the end plate in axial alignment with the waveguide and the reaction chamber. With the antenna in this position, TM modes can be excited, whereas TE modes are excited when the antenna is in the side wall. In other embodiments, the antenna can be placed anywhere in the waveguide.

In the embodiment of FIG. 3, inwardly projecting radial fins 28 are added to the side wall of the waveguide to avoid the need for retuning the source following ignition of the plasma. The need to retune arises because with sources which are capable of operating in multiple resonant modes, mode shifting can occur when the plasma is formed. Retuning serves to minimize reflected power and to operate the source in a stable plasma mode. The fins force the cylindrical microwave structure to resonate or lock in at a specific, or dominant, mode by forcing the electrical field parallel to its surfaces to be zero. The source is thus capable of locking in either a TEₙₚ mode or a TMₙₚ mode, and it will produce a stable, repeatable plasma without retuning.

The fins can be fabricated of metal such as aluminum, a ceramic or a plastic coated with metal, a semiconductor material, or a composite material.

The thickness of the fins is determined by the size of the cavity, the cavity resonant mode desired, and the microwave frequency. The size and shape of the fins are not critical, but they are minimized in order to reduce perturbations in the resonant cavity. The fins are positioned at a height such that a part of each fin is level with the microwave antenna 22 in the side wall. The length of the fins is adjusted in accordance with the size of the cylinder and the microwave frequency.

The number of fins is determined by the size of the cylinder, the desired mode of the cavity, and the microwave frequency. In a TEₙₚ cylindrical mode, for example, a maximum number of 2n fins can be used.

The fins are positioned where the radial component of the electric field is at or near zero. In the TEₙₚ mode, there are 2n such locations around the inner wall of the cylinder, and FIGS. 3 and 4 show the twelve fins for a TE₆₁ mode.

For a TMₙₚ mode, the locations of the metal fins are once again determined by the radial component of the electric field, and are positioned near the cylindrical wall where the electric field is at or near zero. There are 2n such locations.

The embodiment of FIG. 5 is similar to that of FIG. 3 except the dielectric window 29 between the waveguide and the reaction chamber is dome-shaped rather than being flat. This window includes a skirt 31 which forms the side wall of the reaction chamber, with the gas manifold 16 being positioned toward the lower end of the reaction chamber below the skirt.

In another embodiment of the invention, the need for retuning is avoided by sequential microwave excitation during start-up. In this embodiment, the applicator is tuned initially with continuous wave microwave excitation and the plasma running under normal operating conditions. The applicator is then turned off, and microwave pulses are applied for a brief period of time (typically about one second or less) to ignite a weak plasma. Then, before the plasma dies down, continuous wave microwave energy is applied for continuous operation of the plasma. The pulses are typically applied at a frequency of about 500 MHz, a duty cycle of about 50 percent, a power level of about 1 kilowatt, and for a period of about one second.

The microwave pulses can come either from the same source as the continuous wave microwave energy or from a separate source. The frequency of the pulses can be anywhere from a few kilohertz to several gigahertz, and the frequency of the continuous wave microwaves can be between a few hundred megahertz and a few gigahertz, not just 915 MHz or 2.45 GHz. The duration of the pulses can be less than one second, as long as a weak plasma is ignited by them, or it can be longer than one second, if desired. The power level required to ignite the weak plasma depends on the working pressure, gas composition and size of the plasma source. The duty cycle of the pulses can be anywhere between a few percent to over 90 percent. Eliminating the need for retuning eliminates the need for moving parts and thereby increases the reliability and decreases the cost of the equipment.

The invention is suitable for use with large diameter semiconductor wafers, i.e. wafers having a diameter on the order of 200 to 300 mm, and it can be utilized in a wide variety of processes including ashing, stripping, etching, surface modification, plasma immersion implantation and chemical vapor deposition processes.

The invention has a number of important features and advantages. With the relatively flat reaction chamber, process uniformity is enhanced because of more uniform gas distribution over the substrate to be processed. Microwave tuning is also easier because of more uniform microwave distribution in the waveguide, and retuning is not required after the plasma is ignited. The magnets enhance microwave absorption and reduce plasma loss to the chamber wall.

It is apparent from the foregoing that a new and improved microwave plasma reactor and method have been provided. While only certain presently preferred embodiments have been described in detail, as will be apparent to those familiar with the art, certain changes and modifications can be made without departing from the scope of the invention as defined by the following claims.

1. In a reactor for processing a workpiece in an ionized gas plasma: a generally cylindrical reaction chamber which is substantially greater in diameter than in height, means for introducing gas into the chamber, a generally cylindrical waveguide aligned axially with the reaction chamber, an end plate closing the end of the waveguide opposite the reaction chamber, means for introducing microwave energy into the waveguide, and a window which is transparent to microwave energy separating the waveguide from the reaction chamber and permitting the microwave energy to pass from the waveguide to chamber to ionize the gas and form a plasma in the chamber.

2. The reactor of claim 1 wherein the window is fabricated of a dielectric material.

3. The reactor of claim 1 wherein the window is fabricated of a material selected from the group consisting of quartz, alumina and other dielectric materials through which microwaves can pass.

4. The reactor of claim 1 wherein the window is at least as large in diameter as the reaction chamber.

5. The reactor of claim 1 wherein the window is a flat circular disk.

6. The reactor of claim 1 wherein the window is dome shaped.

7. The reactor of claim 1 wherein the pressure in the waveguide is atmospheric pressure, and the pressure in the reaction chamber is on the order of millitorrs to Torrs.

8. The reactor of claim 1 wherein the means for introducing the gas into the reaction chamber comprises an annular manifold which encircles the chamber and includes means for distributing the gas around the chamber in a substantially uniform manner.

9. The reactor of claim 1 wherein the means for introducing microwave energy into the waveguide comprises a microwave antenna mounted on the side wall of the waveguide.

10. The reactor of claim 1 wherein the means for introducing microwave energy into the waveguide comprises a microwave antenna mounted on the end plate.

11. The reactor of claim 1 including a plurality magnets spaced peripherally of the reaction chamber for increasing coupling of the microwave energy to the gas and reducing plasma diffusion loss to the chamber wall.

12. The reactor of claim 1 including a plurality of radial fins projecting inwardly from the side wall of the waveguide and spaced peripherally of the waveguide to promote a desired TE or TM mode in the waveguide.

13. The reactor of claim 12 wherein the fins are positioned in locations where the radial component of the electric field of the microwave energy is zero or near zero.

14. The reactor of claim 12 wherein the fins are fabricated of a material selected from the group consisting of metal, a material coated with metal, a semiconductor material, a composite material, and combinations thereof.

15. The reactor of claim 1 including means for applying the microwave energy to the waveguide in the form of short pulses for a brief period of time to ignite a weak plasma, and thereafter applying the microwave energy to the waveguide in the form of a continuous wave.

16. The reactor of claim 15 wherein the pulses are applied at a rate ranging from a few kilohertz to several gigahertz.

17. The reactor of claim 15 wherein the pulses are applied for a period of about one second or less.

18. The reactor of claim 15 wherein the pulses are applied at a frequency of about 500 MHz, a duty cycle of about 50 percent, a power level of about 1 KW, and for a time period of about one second.

19. In a method of processing a workpiece in an ionized gas plasma: placing the workpiece in a generally cylindrical reaction chamber which is substantially greater in diameter than in height, introducing gas into the chamber, introducing microwave energy into a generally cylindrical waveguide which is aligned axially with the reaction chamber, and passing the microwave energy through a microwave transparent window between the waveguide and the reaction chamber to ionize the gas and form a plasma in the chamber.

20. The method of claim 19 including the steps of maintaining the pressure in the waveguide at atmospheric pressure and the pressure in the reaction chamber on the order of millitorrs to Torrs.

21. The method of claim 19 wherein the gas is introduced into the reaction chamber through peripherally spaced openings in an annular manifold which encircles the chamber.

22. The method of claim 19 wherein the microwave energy is introduced into the waveguide by a microwave antenna mounted on the side wall of the waveguide.

23. The method of claim 19 wherein the microwave energy is introduced into the waveguide by a microwave antenna positioned at the end of the waveguide opposite the reaction chamber.

24. The method of claim 19 including the steps of increasing coupling of the microwave energy to the gas and reducing plasma diffusion loss to the chamber wall with a plurality magnets spaced peripherally of the reaction chamber.

25. The method of claim 19 including the step of spacing a plurality of inwardly projecting radial fins about the side wall of the waveguide to promote a desired TE or TM mode in the waveguide.

26. The method of claim 19 wherein the fins are positioned in locations where the radial component of the electric field of the microwave energy is zero or near zero.

27. The method of claim 19 including the steps of applying the microwave energy to the waveguide in the form of short pulses for a brief period of time to ignite a weak plasma, and thereafter applying the microwave energy to the waveguide in the form of a continuous wave.

28. The method of claim 19 wherein the pulses are applied at a rate ranging from a few kilohertz to several gigahertz.

29. The method of claim 19 wherein the pulses are applied for a period of about one second or less.

30. The method of claim 19 wherein the pulses are applied at a frequency of about 500 MHz, a duty cycle of about 50 percent, a power level of about 1 KW, and for a time period of about one second.

31. In a reactor for processing a workpiece in an ionized gas plasma: a relatively flat, generally cylindrical reaction chamber having a diameter on the order of three times the height of the chamber, means for introducing gas into the chamber, a generally cylindrical waveguide substantially equal in diameter to the reaction chamber and aligned axially with the chamber, a flat end plate closing the end of the waveguide opposite the reaction chamber, means for introducing microwave energy into the waveguide, and a flat circular dielectric window having a diameter at least as great as the reaction chamber separating the waveguide from the reaction chamber and permitting microwaves to pass from the waveguide to reaction chamber to ionize the gas and form a plasma in the chamber.

32. The reactor of claim 31 wherein the window is fabricated of a material selected from the group consisting of quartz, alumina and other dielectric materials through which microwaves can pass.

33. In a reactor for processing a workpiece in an ionized gas plasma: a generally cylindrical reaction chamber, means for introducing gas into the chamber, a generally cylindrical waveguide substantially equal in diameter to the reaction and aligned axially with the chamber, an end plate closing the end of the waveguide opposite the reaction chamber, means for introducing microwave energy into the waveguide, a window separating the waveguide from the reaction chamber and permitting microwaves to pass from the waveguide to reaction chamber to ionize the gas and form a plasma in the chamber, and a plurality of radial fins projecting inwardly from the side wall of the waveguide and spaced peripherally of the waveguide to promote a desired mode within the waveguide.

34. The reactor of claim 33 wherein the fins are positioned in locations where the radial component of the electric field of the microwave energy is zero or near zero.

35. The reactor of claim 33 wherein the fins are fabricated of a material selected from the group consisting of metal, a material coated with metal, a semiconductor material, a composite material, and combinations thereof.

36. The reactor of claim 33 wherein the window is a flat circular disk.

37. The reactor of claim 33 wherein the window is dome shaped.

38. In a reactor for processing a workpiece in an ionized gas plasma: a reaction chamber, means for introducing gas into the reaction chamber, a microwave applicator for applying microwave energy to reaction chamber to ionize the gas and form a plasma, means for applying microwave energy to the applicator in the form of short pulses until a weak plasma is ignited in the reaction chamber, and means for thereafter applying the microwave energy to the applicator in the form of a continuous wave.

39. The reactor of claim 38 wherein the pulses are applied at a rate ranging from a few kilohertz to several gigahertz.

40. The reactor of claim 38 wherein the pulses are applied for a period of about one second or less.

41. In a method of processing a workpiece in an ionized gas plasma, the steps of: placing the workpiece in a reaction chamber, introducing gas into the reaction chamber, applying microwave energy to the reaction chamber in the form of short pulses until a weak plasma is ignited in the chamber, and thereafter applying the microwave energy to the chamber in the form of a continuous wave to form a stronger plasma.

42. The method of claim 41 wherein the pulses are applied at a rate ranging from a few kilohertz to several gigahertz.

43. The method of claim 41 wherein the pulses are applied for a period about one second or less.

44. The method of claim 41 wherein the pulses are applied at a frequency about 500 MHz, a duty cycle of about 50 percent, a power level of about 1 KW, and for a time period of about one second.
